(19) United States
(12) Patent Application Publication
(10) Pub. No.: US 2021/0343852 A1
(43) Pub. Date: Nov. 4, 2021

(54) FIELD-EFFECT TRANSISTOR AND METHOD FOR FABRICATING THE SAME

(71) Applicant: SHANGHAI INSTITUTE OF MICROSYSTEM AND INFORMATION TECHNOLOGY, CHINESE ACADEMY OF SCIENCES, SHANGHAI (CN)

(72) Inventors: ZHONGYING XUE, SHANGHAI (CN); LANTIAN ZHAO, SHANGHAI (CN); QINGTAI ZHAO, SHANGHAI (CN); WENJIE YU, SHANGHAI (CN); ZENGFENG DI, SHANGHAI (CN); MIAO ZHANG, SHANGHAI (CN)

(73) Assignee: SHANGHAI INSTITUTE OF MICROSYSTEM AND INFORMATION TECHNOLOGY, CHINESE ACADEMY OF SCIENCES, SHANGHAI (CN)

(21) Appl. No.: 16/337,556

(22) PCT Filed: Sep. 28, 2018
(86) PCT No.: PCT/CN2018/108302

§ 371 Date: Mar. 28, 2019

(30) Foreign Application Priority Data
Nov. 20, 2017 (CN) 201711155137.4

(51) Int. Cl. H01L 29/423; H01L 29/06; H01L 29/786; H01L 29/161; H01L 29/08; H01L 21/762; H01L 21/308; H01L 21/306; H01L 29/40

(52) U.S. Cl. CPC H01L 29/42392; H01L 29/0673; H01L 29/78696; H01L 29/161; H01L 29/401; H01L 21/76224; H01L 21/308; H01L 21/30604; H01L 29/0847

(57) ABSTRACT

The present disclosure provides a field-effect transistor structure and a method for fabricating the same. The method comprises: providing a substrate, and depositing at least one first material layer and at least one second material layer on a surface of the substrate; defining an active region and a shallow trench isolation region; etching the active region to form a channel region, a source region and a drain region; corroding the first material layer or second material layer in the groove region to obtain at least one nano-wire channel; depositing a dielectric layer and a gate structure layer on a surface of nano-wire channel; and fabricating a gate electrode, a source electrode and a drain electrode on surfaces of the gate structure layer, the source region and the drain region to complete the fabrication of the field-effect transistor.

### BACKGROUND OF THE PRESENT INVENTION

### Technical Field

The present disclosure relates to the technical field of semiconductor device and fabrication thereof, in particular, to a field-effect transistor and a method for fabricating the same.

### Description of Related Arts

In recent years, with the continuous progress of microelectronics technology, device feature size has been reduced and device performance has been increased. The inhibition effect on device performance caused by a series of short-channel effects such as the decrease of leakage-induced potential has been continuously strengthened, which has seriously affected the reliability of devices, and inhibited the improvement of device performance. For this reason, the Fin Field-Effect Transistor (FinFET) becomes the mainstream microelectronics fabrication technology since the 22 nm technology. The multi-gate structure of FinFET greatly improves the control ability of the gate to the device, and promotes the microelectronics technology to advance to 10/7 nm technology all the way.

Compared with the FinFET, nano-wire ring-gate transistor use nano-wire as channel region, the ring-gate fully enclosure the channel region, the size of the device is reduced and the gate control ability is improved to the greatest extent. Therefore, it is possible for nano-wire ring-gate transistor to replace the FinFET in the future microelectronics technology and form a new generation of core device architecture. Ring-gate field-effect transistors are usually fabricated by using SOI materials, silicon nano-wire channel regions are formed by adopting technologies such as photoetching and selective etching. However, the carrier transport capacity of nano-wire field-effect transistor is limited by the diameter of nano-wire, and the performance of device will be affected when the size of device is small. In addition, ion implantation doping is difficult to ensure the uniformity of doping concentration in source and drain regions for stacked structures, the process is complex and the flexibility is not high enough.

Therefore, it is necessary to provide a three-dimensional stacked nano-wire array and a field-effect transistor based on the nano-wire array to solve the above-mentioned problems.

### SUMMARY OF THE PRESENT DISCLOSURE

In view of the above-mentioned disadvantages of the prior art, the purpose of the present disclosure is to provide a field-effect transistor and a method for fabricating the same, which are used for solving the problems such as that the carrier transport capacity of the nano-wire field-effect transistor in the prior art is limited by the diameter of the nano-wire channel and it is difficult to realize source and drain ion implantation.

In order to realize the above-mentioned purpose and other related purposes, the present disclosure provides a method for fabricating a field-effect transistor, comprising the following steps:

1) providing a substrate, and depositing a stacked material layer on a surface of the substrate, wherein the stacked material layer includes at least one first material layer and at least one second material layer which are alternately stacked, the material of the first material layer is different from the material of the second material layer;

2) defining an active region in the stacked material layer and forming a shallow trench isolation region surrounding the active region and running through the stacked material layer;

3) etching the active region to form a channel region, a source region and a drain region, wherein the source region and the drain region are respectively connected to two ends of the channel region;

4) corroding the structure obtained in step 3) and removing the first material layer or the second material layer in the channel region to obtain at least one nano-wire channel;

5) depositing at least a dielectric layer on a surface of nano-wire channel and forming a gate structure layer on a surface of the dielectric layer, wherein a top surface of the dielectric layer is higher than a top surface of the stacked material layer, and when a plurality of nano-wire channels are formed, the dielectric layers on the surfaces of adjacent nano-wire channels are not connected; and

6) respectively fabricating a gate electrode on the surface of the gate structure layer, a source electrode on the surface of the source region, and a drain electrode on the surface of the drain region to complete the fabrication of the field-effect transistor.

As a preferred solution of the present disclosure, in step 2), a shallow trench structure is formed in the stacked material layer by means of a photoetching-etching process to define the active region, and an insulating material layer is filled into the shallow trench structure to form the shallow trench isolation region.

As a preferred solution of the present disclosure, in step 2), the active region comprises a first portion and a second portion located on two sides of the first portion and connected with the first portion, the first portion is used for forming the channel region, and the second portion is used as the source region and the drain region connected to the two ends of the channel region.

As a preferred solution of the present disclosure, in step 3), the step of etching the active region comprises:

3-1) forming an etching mask layer on the surface of the structure obtained in step 2), wherein the etching mask layer cover the region subsequently forming the channel region in the first portion; and

3-2) etching the uncovered region till the substrate is exposed by using the etching mask layer as a mask to obtain the channel region and the source region and the drain region connected to the two ends of the channel region.

As a preferred solution of the present disclosure, in step 5), the dielectric layer is a high-K dielectric layer, the gate structure layer comprises a first portion located on the surface of the dielectric layer, a second portion connected to two sides of the first portion and located on the substrate, and a third portion connected to an exposed end portion of the second portion.

As a preferred solution of the present disclosure, in step 5), before the gate structure layer is formed, the method further comprises a step of forming a metal barrier layer on the surface of the dielectric layer.

As a preferred solution of the present disclosure, in step 5), in step 5), the method further comprises a step of forming a sidewall structure on the surface of the gate structure layer, wherein the sidewall structure fills the etched region of the active region and exposes a top of the gate structure layer for subsequently forming the gate electrode.

As a preferred solution of the present disclosure, in step 6), before the gate electrode, the source electrode and the drain electrode are formed, the method further comprises a step of forming a metal silicide layer on a surface of a top of the gate structure layer, a surface of a top of the source region and a surface of a top of the drain region.

As a preferred solution of the present disclosure, the first material layer is a silicon germanium material layer and the second layer is a silicon material layer.

As a preferred solution of the present disclosure, the silicon germanium material layer is a boron doped or phosphorus doped silicon germanium material layer, wherein doping concentration of boron doping has a range of 1e18 cm⁻³-5e19 cm⁻³; and doping concentration of phosphorus doping has a range of 1e18 cm⁻³-2e19 cm⁻³.

As a preferred solution of the present disclosure, in step 4), mixed solution of hydrofluoric acid, hydrogen peroxide and acetic acid is adopted for removing the first material layer; and tetramethylammonium hydroxide solution is adopted for removing the second material layer.

The present disclosure further provides a field-effect transistor structure, comprising:

a substrate;

a source region and a drain region located on a surface of the substrate and respectively comprising a stacked structure consisting of at least one first material layer and at least one second material layer which are alternately stacked, the material of the first material layer is different from the material of the second material layer;

a channel region comprising at least one nano-wire channel and connected between the source region and the drain region, wherein when the number of the nano-wire channels is more than one, adjacent nano-wire channels are alternately arranged in parallel from top to bottom;

a dielectric layer and a gate structure layer, the dielectric layer is located on a surface of the nano-wire channel, a top surface of the dielectric layer being higher than top surfaces of the source region and the drain region, and the gate structure layer is at least located on the surface of the dielectric layer, wherein when a plurality of nano-wire channels are formed, the dielectric layers on the surfaces of adjacent nano-wire channels are not connected; and

a gate electrode formed on top surface of the gate structure layer, a source electrode formed on top surface of the source region and a drain electrode formed on top surface of the drain region.

As a preferred solution of the present disclosure, the first material layer is a silicon germanium material layer, the material is Si₁₋ₓGeₓ and a range of germanium content x is 0.15-0.6; and the second material layer is a silicon material layer.

As a preferred solution of the present disclosure, the silicon germanium material layer is a P-type doped and N-type doped silicon germanium material layer.

As a preferred solution of the present disclosure, the field-effect transistor structure further comprises a metal barrier layer located between the dielectric layer and the gate structure layer; and a metal silicide layer is respectively formed between the source region and the source electrode, between the drain region and the drain electrode, and between the gate structure layer and the gate electrode.

As a preferred solution of the present disclosure, the length of the nano-wire channel has a range of 10 nm-200 nm; the thickness of the dielectric layer has a range of 5 nm-20 nm; and structures of the gate electrode, the source electrode and the drain electrode are the same and respectively comprise a stacked material layer consisting of a chromium layer and a gold layer, wherein the thickness of the chromium layer has a range of 1 nm-10 nm and the thickness of the gold layer has a range of 150 nm-250 nm.

As described above, the field-effect transistor structure and the method for fabricating the same provided by the present disclosure have the following beneficial effects: In the present disclosure, by using the stacked suspended Si material layer or SiGe material layer as the nano-wire channel region, and by forming a three-dimensional stacked ring-gate nano-wire channel, in the same plane area, the cross-section area of the channel can be increased as much as possible, and the performance of the device is greatly improved; by filling the high-dielectric-constant material as the gate dielectric around the nano-wire channel region to form the ring-gate structure, the gate control ability is improved as much as possible and the stability of the device is improved; the process for fabricating the field-effect transistor in the present disclosure overcomes the limitation of the size of the formed nano-wire channel in the prior art, and by adopting the stacked nano-wire channel, the size of the device is reduced, the carrier transport capacity is improved and the performance of the device is improved at the same time; and the doping steps of the source and drain are omitted in the prevent disclosure, the process is simple, the cost is low and it is suitable for mass production.

### BRIEF DESCRIPTION OF THE DRAWINGS

FIG. 1 illustrates a flowchart of a process for fabricating a field-effect transistor provided by the present disclosure.

FIG. 2 illustrates a top view of a stacked material layer formed in fabrication of a field-effect transistor provided by the present disclosure.

FIG. 3 illustrates a sectional view along the dashed line in FIG. 2.

FIG. 4 illustrates a schematic view of an active region and a shallow trench isolation region formed in fabrication of a field-effect transistor provided by the present disclosure.

FIG. 5 illustrates a sectional view along the dashed line in FIG. 4.

FIG. 6 illustrates a structural schematic view of a channel region, source region, and a drain region formed in fabrication of a field-effect transistor provided by the present disclosure.

FIG. 7 illustrates a sectional view along the dashed line in FIG. 6.

FIG. 8 illustrates a structural schematic view of a nano-wire channel formed in fabrication of a field-effect transistor provided by the present disclosure.

FIG. 9 illustrates a sectional view along the dashed line in FIG. 8.

FIG. 10 illustrates a structural schematic view of a dielectric layer and a gate structure layer formed in fabrication of a field-effect transistor provided by the present disclosure.

FIG. 11 illustrates a sectional view along the dashed line A-A′ in FIG. 10.

FIG. 12 illustrates a sectional view along the dashed line B-B′ in FIG. 10.

FIG. 13 illustrates a structural schematic view of a sidewall structure formed in fabrication of a field-effect transistor provided by the present disclosure.

FIG. 14 illustrates a sectional view along a dashed line in FIG. 13.

FIG. 15 illustrates a schematic view of a gate electrode, a source electrode and a drain electrode formed in fabrication of a field-effect transistor provided by the present disclosure.

FIG. 16 illustrates a sectional view along the dashed line in FIG. 15.

### DESCRIPTION OF COMPONENT REFERENCE SIGNS

| | |
|---|---|
| 11 | Substrate |
| 21 | First material layer |
| 22 | Second material layer |
| 31 | Active region |
| 311 | First portion |
| 312 | Second portion |
| 32 | Shallow trench isolation region |
| 41 | Etching mask layer |
| 51 | Nano-wire channel |
| 52 | Source region |
| 53 | Drain region |
| 61 | Dielectric layer |
| 71 | Gate structure layer |
| 81 | Sidewall structure |
| 91 | Gate electrode |
| 92 | Source electrode |
| 93 | Drain electrode |
| S1-S6 | Step 1)-step 6) |

### DETAILED DESCRIPTION OF THE PREFERRED EMBODIMENTS

The implementation modes of the present disclosure will be described below through specific examples. One skilled in the art can easily understand other advantages and effects of the present disclosure according to content disclosed in the description. The present disclosure may also be implemented or applied through other different implementation modes, and various modifications or changes may be made to all details in the description based on different points of view and applications without departing from the spirit of the present disclosure.

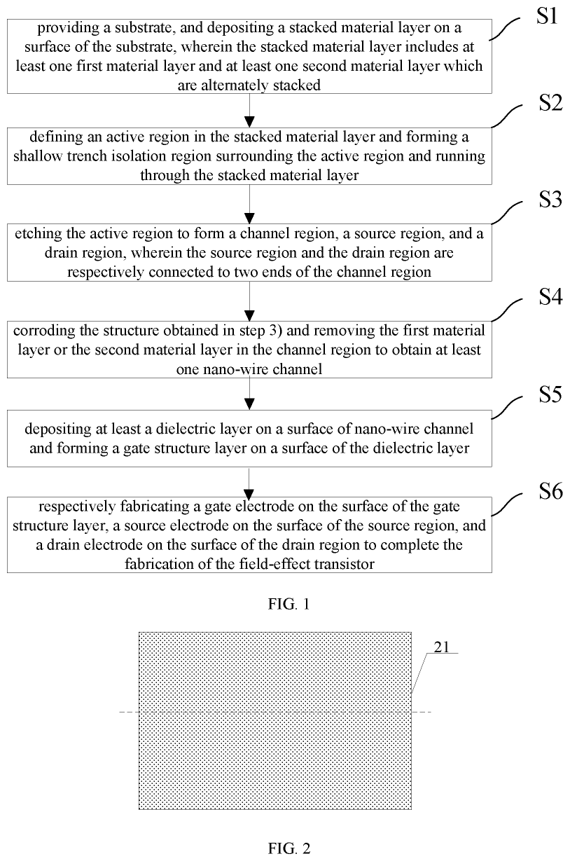

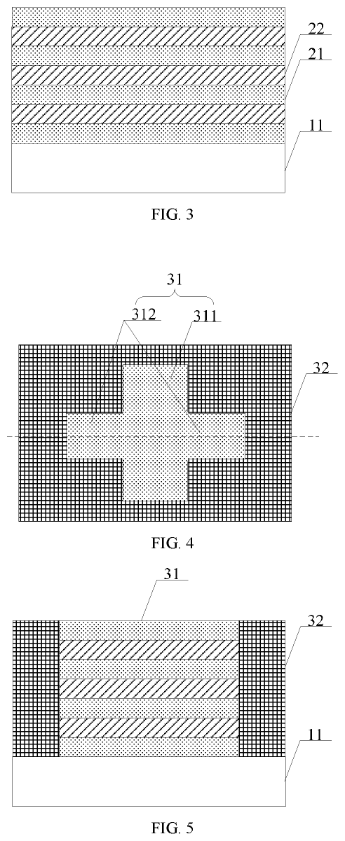

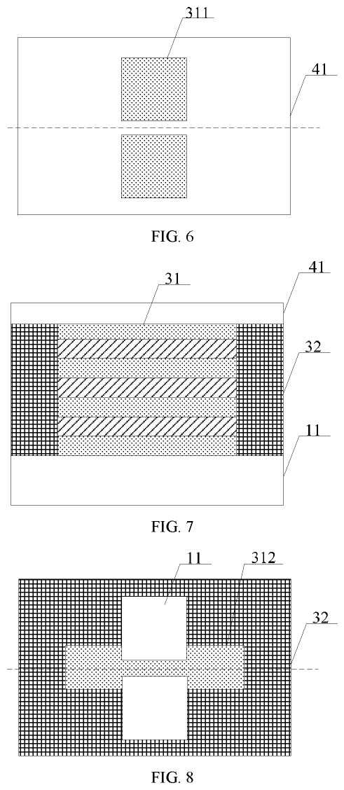

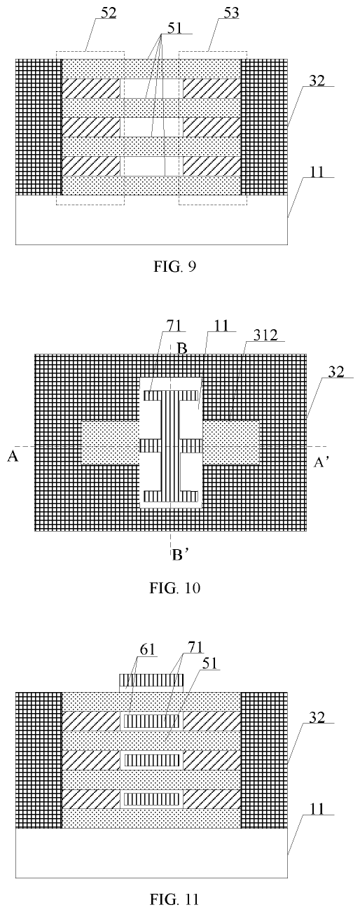

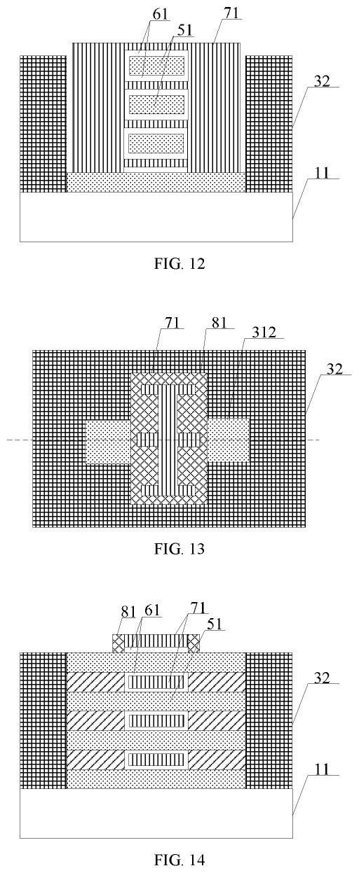

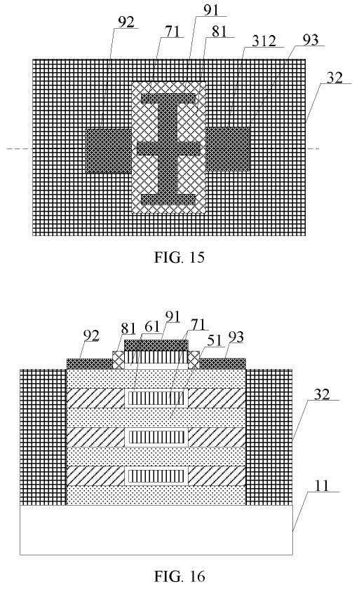

Please refer to FIG. 1 to FIG. 16. It needs to be stated that the drawings provided in the embodiments are just used for schematically describing the basic concept of the present disclosure, thus only illustrate components only related to the present disclosure and are not drawn according to the numbers, shapes and sizes of components during actual implementation, the configuration, number and scale of each component during actual implementation thereof may be freely changed, and the component layout configuration thereof may be more complicated.

As illustrated in FIG. 1, the present disclosure provides a method for fabricating a field-effect transistor, comprising the following steps:

1) providing a substrate, and depositing a stacked material layer on a surface of the substrate wherein the stacked material layer includes at least one first material layer and at least one second material layer which are alternately stacked, the material of the first material layer is different from the material of the second material layer;

2) defining an active region in the stacked material layer and forming a shallow trench isolation region surrounding the active region and running through the stacked material layer;

3) etching the active region to form a channel region, a source region and a drain region, wherein the source region and the drain region are respectively connected to two ends of the channel region;

4) corroding the structure obtained in step 3) and removing the first material layer or the second material layer in the channel region to obtain at least one nano-wire channel;

5) depositing at least a dielectric layer on a surface of nano-wire channel and forming a gate structure layer on a surface of the dielectric layer, wherein a top surface of the dielectric layer is higher than a top surface of the stacked material layer, and when a plurality of nano-wire channels are formed, the dielectric layers on the surfaces of adjacent nano-wire channels are not connected; and

6) respectively fabricating a gate electrode on the surface of the gate structure layer, a source electrode on the surface of the source region, and a drain electrode, on the surface of the drain region to complete the fabrication of the field-effect transistor.

The fabrication of the field-effect transistor in the present disclosure will be described below in detail with reference to the drawings.

As illustrated by Si in FIG. 1 and FIGS. 2-3, step 1), a substrate 11 is provided, and depositing a stacked material layer on a surface of the substrate 11, wherein the stacked material layer includes at least one first material layer 21 and at least one second material layer 22 which are alternately stacked, the material of the first material layer 21 is different from the material of the second material layer 22.

As an example, the first material layer 21 is a silicon germanium material layer, and the second material layer 22 is a silicon material layer.

As an example, the silicon germanium material layer is a boron doped or phosphorus doped silicon germanium material layer, wherein doping concentration of boron is 1e18 cm⁻³-5e19 cm⁻³; and doping concentration of phosphorus is 1e18 cm⁻³-2e19 cm⁻³. Specifically, first a substrate 11 is provided. The substrate 11 may be a silicon material substrate or silicon-on-insulator, etc. In this application, a silicon substrate is selected. In addition, preferably, the first material layer 21 and the second material layer 22 are epitaxially grown on the substrate 11 by means of CVD. The material of the first material layer 21 and the second material layer 22 are different material layers and have different corrosion characteristics for different corrosive liquids, so that one of the first material layer 21 and the second material layer 22 is removed in a subsequent process and the remaining one is used as a channel. Preferably, the first material layer 21 is a silicon germanium material layer, and the second material layer 22 is a silicon material layer, there is no specific restriction on the upper and lower positions of the two materials, and the number of the both layers is at least one, wherein the thickness of the silicon germanium material layer is 5-40 nm, in this example it is 20 nm, the thickness of the silicon material layer is 5-40 nm, in this example it is 40 nm, the thickness can be set according to the actual needs, and preferably, the number of the formed stacked material layers is 3-6.

In addition, the first material layer 21 is a silicon germanium material layer, the material is Si₁₋ₓGeₓ, a range of germanium content x is 0.15-0.6, and Si₁₋ₓGeₓ may be an intrinsic material or N-type doped or P-type doped, wherein, when Si₁₋ₓGeₓ is boron doped, the doping concentration is 1e18 cm⁻³-5e19 cm⁻³, and in this example the doping concentration is 2e19 cm⁻³; and when Si₁₋ₓGeₓ is phosphorus doped, the doping concentration is 1e18 cm⁻³-2e19 cm⁻³, and in this example the doping concentration is 1e19 cm⁻³. As illustrated by S2 in FIG. 1 and FIG. 4-5, step 2), an active region 31 is defined in the stacked material layer, and a shallow trench isolation region 32 surrounding the active region 31 and running through the stacked material layer is formed.

Preferably, a shallow trench structure is first formed in the stacked material layer by adopting an electron beam photoetching and etching process to define the region of the active region 31, wherein the shallow trench structure surrounds the active region 31. The shape of the active region 31 is configured according to the actual situation. Preferably, in this example, the shape of the active region 31 is cross-shaped. Then, an insulating material layer is filled into the shallow trench structure to form the shallow trench isolation region 32. The material of the insulating material layer includes but is not limited to silicon dioxide. In addition, Chemical Vapor Deposition (CVD) may be used to deposit oxides (silicon oxide) and then chemical mechanical polishing may be performed to remove oxides beyond the shallow trench isolation region 32, so as to form the shallow trench isolation region and the active region 31.

As an example, in step 2), the active region 31 comprises a first portion 311 and a second portion 312 located on two sides of the first portion 311 and connected with the first portion, the first portion 311 is used for forming the channel region, and the second portion 312 is used as the source region and the drain region connected to the two ends of the channel region.

Specifically, the active region 31 comprises a first portion used for forming the channel and a second portion used for forming the source region and the drain region. In this example, the active region 31 is cross-shaped, and the cross-section area is subsequently etched to form the channel region, while the active region 31 portion connected to two sides of the channel region is retained and directly serves as the source region and the drain region of the device. That is to say, the source region and drain region in the present disclosure are composed of etched stacked material layers. The present disclosure abandons the implantation and annealing process of the source and drain, and forms an N-type or P-type MOSFET by using a energy band structure difference between silicon/silicon germanium material or directly forming epitaxial SiGe materials with uniform N-type or P-type doping concentration as the source and drain regions, the doping steps of the source and drain are omitted in the fabrication of the field-effect transistor, the process is simple, the cost is low and it is suitable for mass production.

As illustrated by S3 in FIG. 1 and FIG. 6-7, step 3), the active region 31 is etched to form a channel region, a source region 52 and a drain region 53 wherein the source region 52 and the drain region 53 are respectively connected to two ends of the channel region. Preferably, an electron beam photoetching process is used to define the channel region and the patterns of the source and drain regions connected to both ends of the nano-wire. Etching the active region 31 comprises the following steps:

3-1) forming an etching mask layer 41 on the surface of the structure obtained in step 2), wherein the etching mask layer 41 only covers the region subsequently forming the channel region in the first portion; and

3-2) etching the first portion till the substrate 11 is exposed by using the etching mask layer 41 as a mask to obtain the channel region, the source region 52, and the drain region 53, wherein the source region 52 and the drain region 53 are connected to the two ends of the channel region.

Specifically, the etching mask layer 41 masks the regions of the needed channel region and the source region and the drain region, and then other regions of the active region 31 are etched to form the required device structure region.

As illustrated by S4 in FIG. 1 and FIGS. 8-9, step 4), the structure obtained in step 3) is corroded and the first material layer 21 or the second material layer 22 in the channel region is removed to obtain at least one nano-wire channel 51.

Based on the stacked material layer structure formed in step 1) in the present disclosure, one of the first material layer 21 and the second material layer 22 is removed and the other one serves as the nano-wire channel 51, so as to form at least one nano-wire in the device. The length of the nano-wire has a range of 10 nm-200 nm, preferably 50 nm-150 nm. In this example, the length is 100 nm. Reactive Ion Etching (RIE) and anisotropic wet etching are used to form the three-dimensional stacked nano-wire, source region and drain region, and then a ring-gate device structure is formed by the subsequent processes.

A ring-gate field-effect transistor is usually fabricated by using an SOI material. The silicon nano-wire channel 51 is formed by technologies such as photoetching, or selective etching. However, the carrier transport capacity of the nano-wire field-effect transistor is limited by the diameter of nano-wire, and the performance of the device will be affected when the size of the device is small. By forming the three-dimensional stacked ring-gate nano-wire channel 51, in the same plane area, the cross-section area of the channel is increased as much as possible, and the performance of the device is greatly improved.

Herein, as an example, when silicon is used as the channel region to fabricate the transistor, the anisotropic wet etching solution is mixture of hydrofluoric acid (1%), hydrogen peroxide and acetic acid in a ratio of HF:H2O2:CH3COOH=1:2:3 to remove the silicon germanium material layer; and when silicon germanium is used as the channel region to fabricate the transistor, the anisotropic wet etching solution is tetramethylammonium hydroxide (TMAH) to remove the silicon material layer.

As illustrated by S5 in FIG. 1 and FIGS. 10-12, at least a dielectric layer 61 is at least deposited on a surface of nano-wire channel 51, and a gate structure layer 71 is formed on a surface of the dielectric layer 61, wherein a top surface of the dielectric layer 61 is higher than a top surface of the stacked material layer. When a plurality of nano-wire channels 51 are formed, the dielectric layers 61 on the surfaces of adjacent nano-wire channels 51 are not connected

Then, after the formation of the nano-wire channel 51, the dielectric layer 61 is continuously formed as a gate oxide layer. Preferably, a high-dielectric-constant dielectric layer 61 with high dielectric constant is deposited by adopting an Atomic Layer Deposition (ALD) technology. Wherein the thin dielectric layer 61 encapsulates the beam of the nano-wire channel 51, and the upper and lower layers of the nano-wire channel are not connected. When the stacked material layer close to the substrate 11 is removed, the dielectric material may be deposited on the surface of the substrate 11 during the formation of the dielectric layer 61, at this moment, it can be considered that a silicon channel region is on the substrate. In addition, during the deposition of the dielectric layer 61, the dielectric layer 61 will be formed at the cross section of the removed stacked material layer.

In addition, the thickness of the dielectric layer 61 has a range of 5 nm-20 nm, preferably 10 nm-15 nm. In this example, the thickness is 12 nm. Preferably, the dielectric layer 61 is a high-K dielectric layer 61 well known in the art, and the material of the high-K dielectric layer 61 includes alumina, hafnium oxide or the stacked material layer structure of the above-mentioned materials.

Then, a gate structure layer 71 is formed on the surface of the dielectric layer 61, wherein the material of the gate structure layer 71 includes but is not limited to a polycrystalline silicon layer, which is filled into the etched region of the active region 31 and is filled into a space between the upper and lower nano-wire channels 51. Finally, a gate region is formed through photoetching and etching to finally form a ring-gate structure.

Herein, since the stacked suspended silicon or silicon germanium nano-wire is used as the channel, and the high-dielectric-constant material is filled around the channel region as gate dielectric to form the ring-gate structure, the gate control ability is improved to the utmost extent and the stability of the device is improved. By adopting the stacked nano-wire channel 51 structure, the size of the device is reduced, the carrier transport capacity is improved, and the performance of the device is improved.

As an example, the gate structure layer 71 comprises a first portion located on the surface of the dielectric layer 61, a second portion connected to two sides of the first portion and located on the substrate 11, and a third portion connected to an exposed end portion of the second portion.

As an example, the method further comprises a step of forming a metal barrier layer between the dielectric layer 61 and the gate structure layer 71.

Preferably, in this example, the formed gate structure layer 71 comprises three portions, a material layer portion filled in the periphery of the nano-wire channel 51, a second portion perpendicular to the material layer portion and extending into the space of the etched first portion of the active region 31, and a third portion located at two ends of the second portion, so as to provide conditions for subsequently fabricating a gate electrode 91 on the top surface thereof.

The metal barrier layer includes but is not limited to titanium nitride (TiN), the thickness of the metal barrier layer has a range of 2 nm-30 nm, preferably 2 nm-10 nm or 10 nm-30 nm or 15 nm-25 nm. In this example, the thickness is 3 nm.

As an example, in step 5), the method further comprises a step of forming a sidewall structure 81 material layer on the surface of the gate structure layer 71 and finally forming a sidewall structure 81 through photoetching-etching. The sidewall structure 81 fills the etched region of the active region 31 and exposes a top of the gate structure layer 71 for subsequently forming the gate electrode 91.

Specifically, the sidewall material layer is formed on sidewall of the gate layer 71 by adopting a chemical vapor deposition process and finally forming a sidewall structure 81 through photoetching-etching. The material of the sidewall structure 81 includes but is not limited to silicon nitride (Si₃N₄), the thickness of the side structure has a range of 60 nm-200 nm, preferably 100 nm-150 nm, and in this example, the thickness is 120 nm.

As illustrated by S6 in FIG. 1 and FIGS. 13-16, a gate electrode 91 is fabricated on the surface of the gate structure layer 71, a source electrode 92 is fabricated on the surface of the source region, and a drain electrode 93 is fabricated on, the surface of the drain region to complete the fabrication of the field-effect transistor.

As an example, before the gate electrode 91, the source electrode 92 and the drain electrode 93 are formed, the method further comprises a step of forming a metal silicide layer on a surface of a top of the gate structure layer 71, a surface of a top of the source region and a surface of a top of the drain region.

Herein, preferably, structures of the gate electrode 91, the source electrode 92 and the drain electrode 93 are the same, and respectively comprise a stacked material layer consisting of a chromium layer and a gold layer. The thickness of the chromium layer has a range of 1 nm-10 nm, in this example the thickness is 5 nm. The thickness of the gold layer has a range of 150 nm-250 nm, and in this example, the thickness is 200 nm. Of course, the electrodes may be electrodes consisting of other materials, which are not specifically limited herein.

In addition, the method further comprises a step of forming the metal silicide layer. Specifically, a metal layer, such as nickel layer, is formed on the surface of the gate structure layer 71, the surface of the source region and the surface of the drain region. The metal layer is preferably formed by a Physical Vapor Deposition (PVD) process. Then high-temperature annealing is performed to the nickel to form nickel silicide or nickel germanium silicide. Herein, the thickness of the formed metal layer, such as nickel metal layer, has a range of 10 nm-20 nm, preferably 12 nm-18 nm. In this example, the thickness is 15 nm. The annealing temperature is 500° C.-700° C., preferably 550° C.-650° C., and in this example, it is 600° C.

The present disclosure further provides a field-effect transistor structure, wherein the field-effect transistor is obtained preferably by adopting the process for fabricating the field-effect transistor provided by the present disclosure. The field-effect transistor structure comprises:

a substrate 11;

a source region and a drain region located on a surface of the substrate 11, wherein the source region and the drain region each comprises a stacked structure consisting of at least one first material layer 21 and at least one second material layer 22 which are alternately stacked, the material of the first material layer 21 is different from the material of the second material layer 22;

a channel region comprising at least one nano-wire channel 51 and connected between the source region and the drain region, wherein when the number of the nano-wire channels 51 is more than one, adjacent nano-wire channels 51 are alternately arranged in parallel from top to bottom;

a dielectric layer 61 and a gate structure layer 71, wherein the dielectric layer 61 is located on a surface of the nano-wire channel 51, a top surface of the dielectric layer 61 is higher than top surfaces of the source region and the drain region, the gate structure layer 71 is at least located on the surface of the dielectric layer 61, wherein when a plurality of nano-wire channels 51 are formed, the dielectric layers 61 on the surfaces of adjacent nano-wire channels 51 are not connected; and a gate electrode 91 formed on top surface of the gate structure layer 71, a source electrode 92 formed on top surface of the source region, and a drain electrode 93 formed on top surface of the drain region.

As an example, the first material layer 21 is a silicon germanium material layer, the material is Si₁₋ₓGeₓ and a range of germanium content x is 0.15-0.6; and the second material layer 22 is a silicon material layer.

As an example, the silicon germanium material layer is a P-type doped and N-type doped silicon germanium material layer.

Specifically, the substrate 11 may be a silicon material substrate 11 or silicon-on-insulator, etc. In this example, the substrate 11 is a silicon substrate. In addition, the materials of the first material layer 21 and the second material layer 22 are different and have different corrosion characteristics for different corrosive liquids. One of the first material layer 21 and the second material layer 22 is removed in a subsequent process, and the remaining one is used as a channel. Preferably, the first material layer 21 is a silicon germanium material layer, and the second material layer 22 is a silicon material layer. There is no specific restriction on the upper and lower positions of the two materials, and the number of the both layers is at least one. The thickness of the silicon germanium material layer has a range of 5 nm-40 nm, in this example the thickness is 40 nm. The thickness of the silicon material layer is 5 nm-40 nm, in the thickness is 20 nm. The thickness can be set according to the actual needs. Preferably, the number of the formed stacked material layers is 3-6.

In addition, the first material layer 21 is a silicon germanium material layer, the material is Si₁₋ₓGeₓ, a range of germanium content x is 0.15-0.6, and Si₁₋ₓGeₓ may be an intrinsic material or N-type doped or P-type doped, wherein, when Si₁₋ₓGeₓ is boron doped, the doping concentration is 1e18 cm⁻³-5e19 cm⁻³, and preferably 2e19 cm⁻³ in this example; when Si₁₋ₓGeₓ is phosphorus doped, the doping concentration is 1e18 cm⁻³-2e19 cm⁻³, and preferably 1e19 cm⁻³ in this example.

Specifically, the shallow trench structure surrounds the active region 31. The shape of the active region 31 is configured according to the actual situation. Preferably, in this example, the shape of the active region 31 is cross-shaped. An insulating material layer is filled into the shallow trench structure to form the shallow trench isolation region 32, and the material of the insulating material layer includes but is not limited to silicon dioxide.

It needs to be noted that the present disclosure abandons the implantation and annealing process of the source and drain, and forms an N-type or P-type MOSFET by using an energy band difference between silicon/silicon germanium material or directly forming epitaxial SiGe materials with uniform N-type or P-type doping concentration as the source and drain regions, the doping steps of the source and drain are omitted in the fabrication of the field-effect transistor, the process is simple, the cost is low and it is suitable for mass production.

As an example, the field-effect transistor structure further comprises a metal barrier layer located between the dielectric layer 61 and the gate structure layer 71; and metal silicide layers are formed between the source region and the source electrode 92, between the drain region and the drain electrode 93, and between the gate structure layer 71 and the gate electrode 91.

The metal barrier layer includes but is not limited to titanium nitride (TiN), the thickness of the metal barrier layer has a range of 2 nm-30 nm, preferably 2 nm-10 nm or 10 nm-30 nm or 15 nm-25 nm. In this example, the thickness is 3 nm. In addition, the metal silicide layer includes but is not limited to nickel silicide or nickel germanium silicide, the thickness of the metal silicide layer has a range of 10 nm-20 nm, preferably 12 nm-18 nm, and in this example it is 15 nm.

As an example, the length of the nano-wire channel 51 has a range of 10 nm-200 nm; the thickness of the dielectric layer 61 has a range of 5 nm-20 nm; and structures of the gate electrode 91, the source electrode 92 and the drain electrode 93 are the same and respectively comprise a stacked material layer consisting of a chromium layer and a gold layer, wherein the thickness of the chromium layer has a range of 1 nm-10 nm and the thickness of the gold layer has a range of 150 nm-250 nm.

Specifically, the length of the nano-wire has a range of 10 nm-200 nm, preferably 50 nm-150 nm, and in this example it is 100 nm. Preferably, the dielectric layer 61 is a high-K dielectric layer 61 well known in the art, and the material of the high-K dielectric layer 61 includes alumina, hafnium oxide or the stacked material layer structure of the above-mentioned materials. In addition, structures of the gate electrode 91, the source electrode 92 and the drain electrode 93 are the same and respectively comprise a stacked material layer consisting of a chromium layer and a gold layer. The thickness of the chromium layer has a range of 1 nm-10 nm, in this example it is 5 nm. The thickness of the gold layer has a range of 150 nm-250 nm, and in this example it is 200 nm. Of course, the electrodes may be electrodes consisting of other materials, which are not specifically limited herein.

It needs to be noted that, since the device uses the stacked suspended silicon or silicon germanium nano-wire as the channel and the high-dielectric-constant material is filled around the channel region as gate dielectric to form the ring-gate structure, the gate control ability is improved to the utmost extent and the stability of the device is improved. By adopting the stacked nano-wire channel 51 structure, the size of the device is reduced, the carrier transport capacity is improved, and the performance of the device is improved.

To sum up, the present disclosure provides a field-effect transistor and a method for fabricating the same. The method comprises: providing a substrate, and depositing a stacked material layer consisting of at least one first material layer and at least one second material layer which are alternately stacked on a surface of the substrate, the material of the first material layer is different from the material of the second material layer; defining an active region in the stacked material layer and forming a shallow trench isolation region surrounding the active region and running through the stacked material layer; etching the active region to form a channel region, and a source region and a drain region which are respectively connected to two ends of the channel region; corroding the structure obtained in the previous step and removing the first material layer or the second material layer in the channel region to obtain at least one nano-wire channel; at least depositing a dielectric layer on a surface of nano-wire channel and forming a gate structure layer on a surface of the dielectric layer, wherein a top surface of the dielectric layer is higher than a top surface of the stacked material layer, and when a plurality of nano-wire channels are formed, the dielectric layers on the surfaces of adjacent nano-wire channels are not connected; and respectively fabricating a gate electrode, a source electrode and a drain electrode on the surface of the gate structure layer, the surface of the source region and the surface of the drain region to complete the fabrication of the field-effect transistor. By adopting the above-mentioned solution, by using the stacked suspended Si material layer or SiGe material layer as the nano-wire channel region, and by forming a three-dimensional stacked ring-gate nano-wire channel, in the same plane area, the cross-section area of the channel is increased as much as possible, and the performance of the device is greatly improved. By filling the high-dielectric-constant material as the gate dielectric around the nano-wire channel region to form the ring-gate structure, the gate control ability is improved as much as possible and the stability of the device is improved. The process for fabricating the field-effect transistor in the present disclosure overcomes the limitation of the size of the formed nano-wire channel in the prior art, and by adopting the stacked nano-wire channel, the size of the device is reduced, the carrier transport capacity is improved and the performance of the device is improved at the same time. The doping steps of the source and drain are omitted in the prevent disclosure, the process is simple, the cost is low and it is suitable for mass production. Therefore, the present disclosure effectively overcomes various disadvantages in the prior art and thus has a great industrial utilization value.

The above-mentioned embodiments are only used for exemplarily describing the principle and effects of the present disclosure instead of limiting the present disclosure. One skilled in the art may make modifications or changes to the above-mentioned embodiments without departing from the spirit and scope of the present disclosure. Therefore, all equivalent modifications or changes made by those who have common knowledge in the art without departing from the spirit and technical thought disclosed by the present disclosure shall be still covered by the claims of the present disclosure.

1. A method for fabricating a field-effect transistor, comprising following steps:
1) providing a substrate, and depositing a stacked material layer on a surface of the substrate, wherein the stacked material layer includes at least one first material layer and at least one second material layer which are alternately stacked, the material of the first material layer is different from the material of the second material layer;
2) defining an active region in the stacked material layer and forming a shallow trench isolation region surrounding the active region and running through the stacked material layer;
3) etching the active region to form a channel region, a source region, and a drain region, wherein the source region and the drain region are respectively connected to two ends of the channel region;
4) corroding the structure obtained in step 3) and removing the first material layer or the second material layer in the channel region to obtain at least one nano-wire channel;
5) depositing at least a dielectric layer on a surface of nano-wire channel and forming a gate structure layer on a surface of the dielectric layer, wherein a top surface of the dielectric layer is higher than a top surface of the stacked material layer, and when a plurality of nano-wire channels are formed, the dielectric layers on the surfaces of adjacent nano-wire channels are not connected; and
6) respectively fabricating a gate electrode on the surface of the gate structure layer, a source electrode on the surface of the source region, and a drain electrode on the surface of the drain region to complete the fabrication of the field-effect transistor.

2. The method for fabricating the field-effect transistor according to claim 1, wherein in step 2), a shallow trench structure is formed in the stacked material layer by means of a photoetching-etching process to define the active region, an insulating material layer is filled into the shallow trench structure to form the shallow trench isolation region.

3. The method for fabricating the field-effect transistor according to claim 1, wherein in step 2), the active region comprises a first portion and a second portion located on two sides of the first portion and connected with the first portion, the first portion is used for forming the channel region, and the second portion is used as the source region and the drain region connected to the two ends of the channel region.

4. The method for fabricating the field-effect transistor according to claim 3, wherein in step 3), etching the active region comprises:
3-1) forming an etching mask layer on the surface of the structure obtained in step 2), wherein the etching mask layer cover the region subsequently forming the channel region in the first portion; and
3-2) etching the uncovered region till the substrate is exposed by using the etching mask layer as a mask to obtain the channel region and the source region and the drain region connected to the two ends of the channel region.

5. The method for fabricating the field-effect transistor according to claim 1, wherein in step 5), the dielectric layer is a high-K dielectric layer, the gate structure layer comprises a first portion located on the surface of the dielectric layer, a second portion connected to two sides of the first portion and located on the substrate, and a third portion connected to an exposed end portion of the second portion.

6. The method for fabricating the field-effect transistor according to claim 1, wherein in step 5), before the gate structure layer is formed, the method further comprises a step of forming a metal barrier layer on the surface of the dielectric layer.

7. The method for fabricating the field-effect transistor according to claim 1, wherein in step 5), the method further comprises a step of forming a sidewall structure on the surface of the gate structure layer, wherein the sidewall structure fills the etched region of the active region and exposes a top of the gate structure layer for subsequently forming the gate electrode.

8. The method for fabricating the field-effect transistor according to claim 1, wherein in step 6), before the gate electrode, the source electrode and the drain electrode are formed, the method further comprises a step of forming a metal silicide layer on a surface of a top of the gate structure layer, a surface of a top of the source region and a surface of a top of the drain region.

9. The method for fabricating the field-effect transistor according to claim 1, wherein the first material layer is a silicon germanium material layer and the second layer is a silicon material layer.

10. The method for fabricating the field-effect transistor according to claim 9, wherein the silicon germanium material layer is a boron doped or phosphorus doped silicon germanium material layer, wherein doping concentration of boron doping has a range of 1e18 cm⁻³-5e19 cm⁻³; and doping concentration of phosphorus doping has a range of 1e18 cm⁻³-2e19 cm⁻³.

11. The method for fabricating the field-effect transistor according to claim 9, wherein in step 4), mixed solution of hydrofluoric acid, hydrogen peroxide and acetic acid is adopted for removing the first material layer; and tetramethylammonium hydroxide solution is adopted for removing the second material layer.

12. A field-effect transistor, comprising:
a substrate;
a source region and a drain region located on a surface of the substrate and respectively comprising a stacked structure consisting of at least one first material layer and at least one second material layer which are alternately stacked, wherein the material of the first material layer is different from the material of the second material layer;
a channel region comprising at least one nano-wire channel and connected between the source region and the drain region, wherein when the number of the nano-wire channels is more than one, adjacent nano-wire channels are alternately arranged in parallel from top to bottom;
a dielectric layer and a gate structure layer, wherein the dielectric layer is located on a surface of the nano-wire channel, a top surface of the dielectric layer is higher than top surfaces of the source region and the drain region, the gate structure layer is at least located on the surface of the dielectric layer, wherein when a plurality of nano-wire channels are formed, the dielectric layers on the surfaces of adjacent nano-wire channels are not connected; and
a gate electrode formed on top surface of the gate structure layer, a source electrode formed on top surface of the source region and a drain electrode formed on top surface of the drain region.

13. The field-effect transistor structure according to claim 12, wherein the first material layer is a silicon germanium material layer, the material is Si₁₋ₓGeₓ and a range of germanium content x is 0.15-0.6; and the second material layer is a silicon material layer.

14. The field-effect transistor structure according to claim 13, wherein the silicon germanium material layer is a P-type doped and N-type doped silicon germanium material layer.

15. The field-effect transistor structure according to claim 12, wherein the field-effect transistor structure further comprises a metal barrier layer located between the dielectric layer and the gate structure layer; and a metal silicide layer is respectively formed between the source region and the source electrode, between the drain region and the drain electrode, and between the gate structure layer and the gate electrode.

16. The field-effect transistor structure according to claim 12, wherein the length of the nano-wire channel has a range of 10 nm-200 nm; the thickness of the dielectric layer has a range of 5 nm-20 nm; and structures of the gate electrode, the source electrode and the drain electrode are the same and respectively comprise a stacked material layer consisting of a chromium layer and a gold layer, wherein the thickness of the chromium layer has a range of 1 nm-10 nm and the thickness of the gold layer has a range of 150 nm-250 nm.
